(19) United States
(12) Patent Application Publication
(10) Pub. No.: US 2009/0001402 A1
(43) Pub. Date: Jan. 1, 2009

(54) Semiconductor element and method of making the same

(75) Inventor: Mitsuhiko Sakai, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/725,178

(22) Filed: Mar. 16, 2007

(30) Foreign Application Priority Data
Mar. 22, 2006 (JP) 2006-078623
Mar. 30, 2006 (JP) 2006-095275

(51) Int. Cl. H01L 33/00

(52) U.S. Cl. 257/99; 438/46; 257/E33.062

(57) ABSTRACT

A semiconductor light-emitting element includes a nitride semiconductor layer with an active layer. The nitride semiconductor layer has a main surface formed with a first bonding layer made of gold or an alloy of gold and tin. The first bonding layer is bonded to a second bonding layer made of gold or an alloy of gold and tin. The second bonding layer is bonded to a support layer which has a thermal conductivity not smaller than 100 W/mK. The first bonding layer and the second bonding layer have a total thickness not smaller than 5 μm.

### BACKGROUND OF THE INVENTION

1. Field of the Invention

The present invention relates to a semiconductor element, in particular to a semiconductor light-emitting element including a nitride semiconductor layer. The present invention also relates to a method of making such a semiconductor element.

2. Description of the Related Art

As known in the art, white light-emitting diodes (LEDs) have a long life, and their power consumption is small. For these features, white LEDs are used as a light source for liquid crystal display devices in mobile telephones for example. In other applications, it is expected that white LEDs will replace fluorescent or incandescent lighting appliances in the future. The current white LEDs, however, have a small output capacity of e.g. about a few watts, and the need for much brighter white LEDs has arisen. With a type of white LED incorporating blue and yellow LEDs, the brightness of the blue LED needs to be increased in order to improve the brightness of the white LED.

A blue LED has a nitride semiconductor layer including an active layer for generating light. Brightness improvement in blue LEDs can be achieved by e.g. increasing the internal quantum efficiency of the nitride semiconductor layer. In recent years, efforts are being made for development of techniques to increase the internal quantum efficiency of the nitride semiconductor layer.

JP-A-2002-76521 discloses a nitride semiconductor light-emitting element manufactured by using the above-described technique. Specifically, as shown in FIG. 13, the conventional light-emitting element includes a sapphire growth substrate 210, an n-type semiconductor layer 220, an MQW active layer 230, a p-type semiconductor layer 240, a p-electrode 250, and an n-electrode 260. The n-type semiconductor layer 220, the MQW active layer 230, and the p-type semiconductor layer 240 constitute a nitride semiconductor layer which contains at least In—Ga—N. The growth substrate 210 has a crystal lattice similar to those of the nitride semiconductor layers 220-240. Thus, the nitride semiconductor layers 220-240 have good crystallinity, and therefore have improved internal quantum efficiency.

However, the above light-emitting element has following disadvantages. First, in operating the light-emitting element, the heat generated in the nitride semiconductor layer is not effectively dissipated to the outside due to the poor thermal conduction of sapphire constituting the growth substrate 210. Second, the output characteristics of the nitride semiconductor is not good. This is because the temperature of the semiconductor light-emitting element is raised enough to cause thermal saturation by the heat generation at or near the growth substrate 210 when a large amount of electric current is applied to the semiconductor light-emitting element for increasing the light output from the element.

Another example of a conventional semiconductor light-emitting element is disclosed in JP-A-2003-168820. As shown in FIG. 14, this conventional light-emitting element includes a support substrate 491, semiconductor layers 492-494, a p-side electrode 491a, and an n-side electrode 494a. The semiconductor layer is constituted by a p—GaN layer 492, an active layer 493 and an n—GaN layer 494. The light-emitting element as the above is manufactured in the following manner. First, the semiconductor layer is formed on a sapphire growth substrate. Next, the support substrate is bonded to the semiconductor layer on the oppose side to the growth substrate. Thereafter, the growth substrate is heated by laser to be removed from the semiconductor layer.

The removal of the sapphire growth substrate solved the problem which was described with reference to FIG. 13. However, if the support substrate 491 shown in FIG. 14 is too thin, the support substrate 491 may break in the manufacturing process of the light-emitting element. If the support substrate 491 is too thick, on the other hand, then the following problems will occur. During the manufacturing process, the above-mentioned layers are formed on a support substrate of a large size, and the superstructure is divided into a plurality of semiconductor light-emitting elements by dicing. At this step, the support substrate 491, which is adhered to a dicing tape, may come off the dicing tape. This deteriorates the yield rate of the conventional manufacturing method.

### SUMMARY OF THE INVENTION

The present invention has been proposed under the above-described circumstances. It is therefore an object of the present invention to provide a technique enabling efficient manufacture of a semiconductor light-emitting element superior in heat dissipation.

A first aspect of the present invention provides a semiconductor light-emitting element. The semiconductor light-emitting element includes a nitride semiconductor layer which has at least an active layer. The nitride semiconductor layer has a main surface formed with a first bonding layer provided by a layer of gold or of an alloy of gold and tin, and to this first bonding layer is bonded a second bonding layer provided by a layer of gold or of an alloy of gold and tin. The second bonding layer is bonded to a support substrate which has a thermal conductivity not smaller than 100 W/mK. The total thickness of the first and second bonding layers is not smaller than 5 μm.

With the above arrangement, the heat generated in the nitride semiconductor layer is transferred to the support substrate through the first bonding layer and the second bonding layer having a high thermal conductivity. In addition, the support substrate has a sufficient heat dissipation capability, and therefore can dissipate the transferred heat effectively. Accordingly, even if a large amount of electric current is applied to increase the output of light emitted from the light-emitting element, the output characteristics does not deteriorate as in the conventional devices.

A second aspect of the present invention provides a method of manufacturing a semiconductor light-emitting element. According to the method, a nitride semiconductor layer which includes at least an active layer is formed on a growth substrate. A first bonding layer provided by a layer of gold or of an alloy of gold and tin is formed on a main surface of the nitride semiconductor layer. A second bonding layer provided by a layer of gold or of an alloy of gold and tin is formed on a main surface of a support substrate having a thermal conductivity not smaller than 100 W/mK. The second bonding layer (formed on the main surface of the support substrate) and the first bonding layer are bonded to each other under a pressure at a eutectic temperature of the first and the second bonding layers. Then, the growth substrate is removed from the nitride semiconductor layer. The first bonding layer and the second bonding layer after bonded to each other have a total thickness not smaller than 5 μm.

With this method, it is possible to make the above-described semiconductor light-emitting element efficiently. It should be noted that the first bonding layer and the second bonding layer are bonded to each other under a pressure at their eutectic temperature and become an alloy. Accordingly, the bonding strength between the first bonding layer and the second bonding layer is high. This strong bonding is obtainable by a temperature lower than the respective melting temperatures of the first and the second bonding layers.

A third aspect of the present invention provides a semiconductor light-emitting element. The semiconductor light-emitting element includes a substrate, a p-type semiconductor layer supported by the substrate, an n-type semiconductor layer disposed farther away from the substrate than the p-type semiconductor layer, and an active layer disposed between the p-type and the n-type semiconductor layers. The substrate has a thickness not smaller than 200 μm and not greater than 1000 μm.

With the above arrangement, the substrate whose thickness is not smaller than 200 μm is not broken unexpectedly during the manufacturing process of the semiconductor light-emitting element. Further, by choosing the thickness of the substrate not to be greater than 1000 μm, the substrate is flexible enough. Thus, at the time of dicing the substrate with a dicing tape attached, it is possible to prevent the substrate from coming off the dicing tape.

Preferably, the substrate is made of Cu or AlN.

According to such an arrangement, the substrate can appropriately dissipate the heat generated by the semiconductor light-emitting element in use.

Other features and advantages of the present invention will become clearer from the following description of the preferred embodiments.

### BRIEF DESCRIPTION OF THE DRAWINGS

FIG. 1 is a sectional view showing a semiconductor light-emitting element according to a first embodiment of the present invention.

FIG. 2 is a flowchart showing a method of manufacturing the semiconductor light-emitting element in FIG. 1.

FIG. 3 is a sectional view showing the state after a layering step in FIG. 2.

FIG. 4 is a sectional view showing the state after a bonding layer forming step in FIG. 2.

FIG. 5 shows weight composition of Au and Sn in the bonding layer of the semiconductor light-emitting element in FIG. 1.

FIG. 6 is a sectional view showing the state after a bonding step in FIG. 2.

FIG. 7 is a sectional view showing a semiconductor light-emitting element according to a second embodiment of the present invention.

FIG. 8 is a sectional view showing a step of forming a semiconductor layer on a sapphire substrate in a manufacturing process of the semiconductor light-emitting element in FIG. 7.

FIG. 9 is a sectional view showing an etching step of the semiconductor layer in the manufacturing process of the semiconductor light-emitting element in FIG. 7.

FIG. 10 is a sectional view showing a step of forming a reflection layer in the manufacturing process of the semiconductor light-emitting element in FIG. 7.

FIG. 11 is a sectional view showing a step of removing a sapphire substrate in the manufacturing process of the semiconductor light-emitting element in FIG. 7.

FIG. 12 is a sectional view showing a step of forming a plurality of projections in the manufacturing process of the semiconductor light-emitting element in FIG. 7.

FIG. 13 shows a structure of a section of a conventional semiconductor light-emitting element.

FIG. 14 is a sectional view of another conventional semiconductor light-emitting element.

### DETAILED DESCRIPTION OF THE PREFERRED EMBODIMENTS

Preferred embodiments of the present invention will be described below with reference to the accompanying drawings.

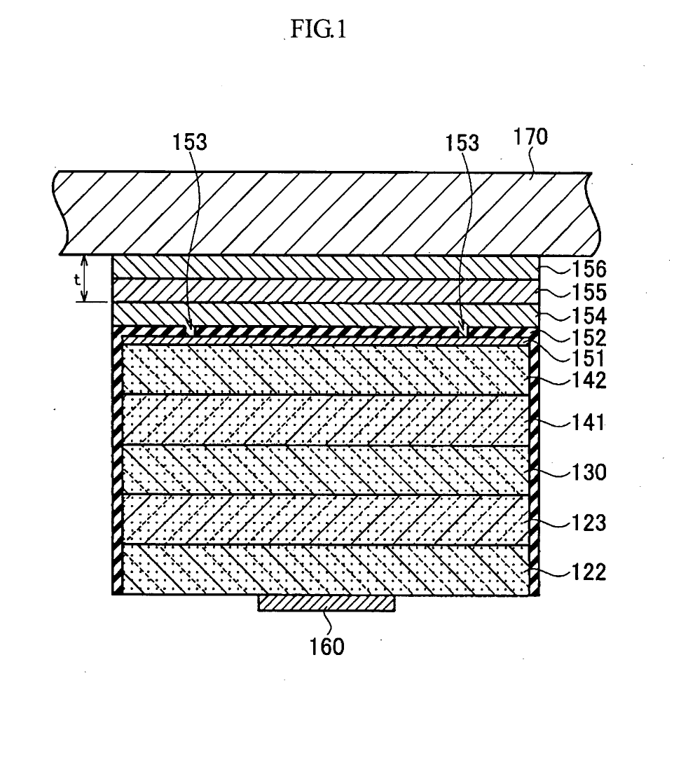

A first embodiment of the semiconductor light-emitting element according to the present invention will be described with reference to FIGS. 1-6.

As shown in FIG. 1, the semiconductor light-emitting element according to the present embodiment includes nitride semiconductor layers 122-142, an n-electrode 160 and a transparent electrode 151. The nitride semiconductor layer includes an n-type contact layer 122, an n-type superlattice layer 123, an MQW active layer 130, a p-type clad layer 141 and a p-type contact layer 142. Further, the semiconductor light-emitting element includes an insulation layer 152, a reflection mirror layer 154, a first bonding layer 155, a second bonding layer 156, and a support substrate 170. The insulation layer 152 covers side surfaces of the nitride semiconductor layer, as well as side surfaces and an upper surface of the transparent electrode 151.

The n-type contact layer 122 is provided by Si-doped GaN, and makes ohmic contact with the n-electrode 160.

The n-type superlattice layer 123 has a superlattice structure constituted by alternate layering of an In—Ga—N layer provided by Si-doped In—Ga—N and a GaN layer provided by Si-doped GaN.

The MQW active layer 130 has an MQW (Multi Quantum Well) structure formed by nitride semiconductors which contain In. For example, the MQW active layer 130 is structured by eight alternate layers of a 3-nm thick well layer provided by In_{0.17}GaN and a 10-nm thick barrier layer provided by undoped GaN.

The p-type clad layer 141 is provided by undoped GaN or In_{0.01}GaN which contains about 1% of In. The p-type contact layer 142 is provided by Mg-doped GaN. The p-type contact layer 142 makes ohmic contact with the transparent electrode 151.

The n-electrode 160 is constituted by a Ti layer formed on the n-type contact layer 122, and an Al layer formed thereon. Alternatively, the n-electrode 160 may be provided by an Al layer alone.

The transparent electrode 151 is formed of Ga-doped ZnO on the p-type contact layer 142.

The insulation layer 152 is formed of SiN, etc. The insulation layer 152 has a contact hole 153 for making electric contact between the transparent electrode 151 and the reflection mirror layer 154.

The reflection mirror layer 154 is provided by an Al layer formed on the insulation layer 152. The reflection mirror layer 154 makes contact with the transparent electrode 151 through a contact hole 153, so it is possible to apply electric current from the reflection mirror layer 154 to the transparent electrode 151. The reflection mirror layer 154 reflects light emitted from the p-type contact layer 142, thereby improving beam extraction efficiency from the n-type contact layer 122. The reflection mirror layer 154 may not necessarily be formed of Al, but may be formed of other silver white metals (such as Ag). As another alternative, the reflection mirror layer 154 may be formed by alternate layers of an Al layer and a Ti layer.

The first bonding layer 155 is a layer of gold (Au) or a layer of a gold-tin (Sn) alloy formed to sandwich the transparent electrode 151 through the reflection mirror layer 154 on a main surface of the nitride semiconductor layer. The second bonding layer 156 is also a layer of Au or a layer of an Au—Sn alloy like the first bonding layer 155, and is bonded to the first bonding layer 155. The first bonding layer 155 and the second bonding layer 156 have a total thickness t which is not smaller than 5 μm.

The support substrate 170 is bonded to the second bonding layer 156. The support substrate 170 is formed of a material (such as Cu, AlN) which has a thermal conductivity not smaller than 100 W/mK.

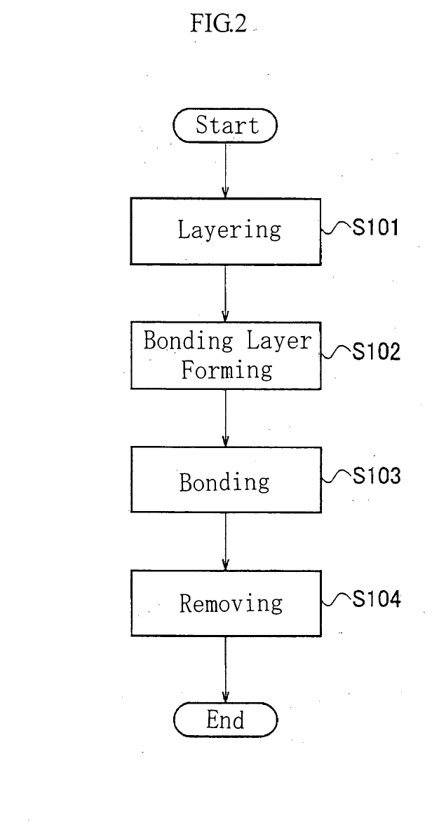

Next, reference will be made to FIG. 2 through FIG. 6 to describe a method of manufacturing the semiconductor light-emitting element.

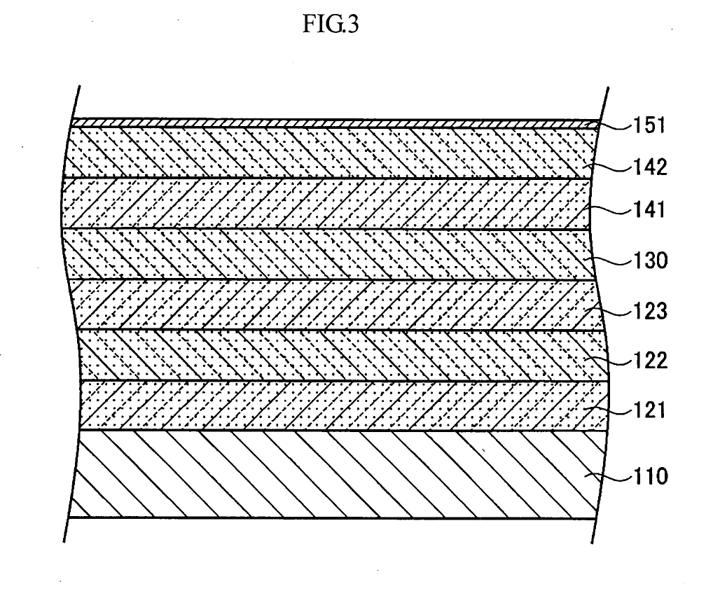

First, Step S101 in FIG. 2, i.e. a layering step, is performed. As shown in FIG. 3, this step is a process of forming nitride semiconductor layers (121 through 142) and a transparent electrode 151 on a sapphire growth substrate 110.

Specifically, first, the growth substrate 110 is placed into a metal organic chemical vapor depositor (hereinafter called MOCVD). Then, while supplying hydrogen gas into the depositor, the inner temperature is raised to about 1050° C., to perform thermal cleaning of the growth substrate 110. Next, the temperature in the MOCVD is lowered to about 600° C., to grow an n-type buffer layer 121 of GaN on the growth substrate 110 by epitaxis.

Next, the temperature in the MOCVD is raised to about 1000° C., to grow an n-type contact layer 122 of Si-doped GaN on the n-type buffer layer 121 by epitaxis.

Next, an n-type superlattice layer 123 is epitaxially grown on the n-type contact layer 122. The n-type superlattice layer 123 is formed by alternately layering an Si-doped In—Ga—N layer and an Si-doped GaN layer.

Next, an MQW active layer 130 having an MQW structure is epitaxially grown on the n-type superlattice layer 123, by alternately layering a 3 nm-thick well layer of In_{0.17} GaN and a 10 nm-thick barrier layer of undoped GaN, eight times for each of the layers.

Next, a p-type clad layer 141 provided by an undoped GaN layer or an In—Ga—N layer containing about 1% of In is grown on the MQW active layer 130 by epitaxis.

Next, while raising the temperature in the MOCVD further, a p-type contact layer 142 of Mg-doped GaN is epitaxially grown on the p-type clad layer 141. This completes the formation of the nitride semiconductor layers. Finally, a transparent electrode 151 of Ga-doped ZnO having a resistance of about 2×10⁻⁴ Ωcm is formed on the p-type contact layer 142 by molecular beam epitaxy.

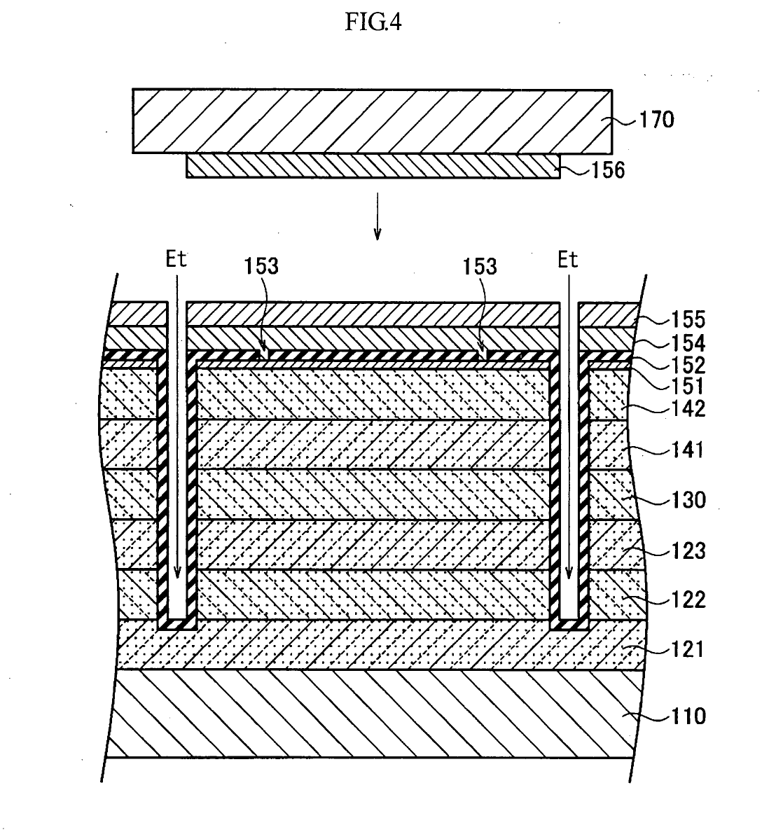

Following the layering step, Step S102 in FIG. 2, i.e. a bonding layer forming step, is performed. This step is a step of forming a structure shown in FIG. 4, by forming a first bonding layer 155 on the nitride semiconductor layer and a second bonding layer 156 on the support substrate 170.

Specifically, the first bonding layer 155 is formed in the following procedure: First, etching is performed to the transparent electrode 151 and the nitride semiconductor layer (See Arrows Et in FIG. 4) to form predetermined cut grooves. The grooves will be used in a later step when the nitride semiconductor layer is divided into individual semiconductor light-emitting elements. The etching is performed by means of inductive coupled plasma (ICP) for example, until the n-type buffer layer 121 of the nitride semiconductor is exposed. As will be understood easily, a mask which has a pattern corresponding to the cut grooves is formed on the transparent electrode 151 before the etching is performed. The mask can be formed of a dielectric material such as SiO₂ or a resist material.

Next, an insulation layer 152 of SiN, etc. is formed on exposed surfaces of the transparent electrode 151 and the nitride semiconductor layer by P-CVD (Plasma Chemical Vapor Deposition), spattering, etc. The insulation layer 152 is also formed on side and bottom surfaces of each cut groove.

Next, contact holes 153 are formed in the insulation layer 152 by dry etching with a CF4 gas. Each contact hole 153 is made on a predetermined location of the transparent electrode 151. The dry etching of this sort is appropriately slow on the transparent electrode 151 which is made of ZnO. Therefore, it is possible to etch virtually the insulation layer 152 only.

After the dry etching, a reflection mirror layer 154 of Al is formed on the insulation layer 152 by vapor deposition. The reflection mirror layer 154 formed in such a way fills each contact hole 153 and makes contact with the transparent electrode 151. As has been described, the reflection mirror layer 154 may be formed of Al, a silver white metal other than Al or may be provided by a combination of an Al layer and a Ti layer.

Next, the first bonding layer 155 of an Au—Sn alloy layer or of an Au layer is formed on the reflection mirror layer 154 by vapor deposition. Likewise, the second bonding layer 156 is formed on the support substrate 170, by vapor deposition. The support substrate 170 has a thermal conductivity not smaller than 100 W/mK.

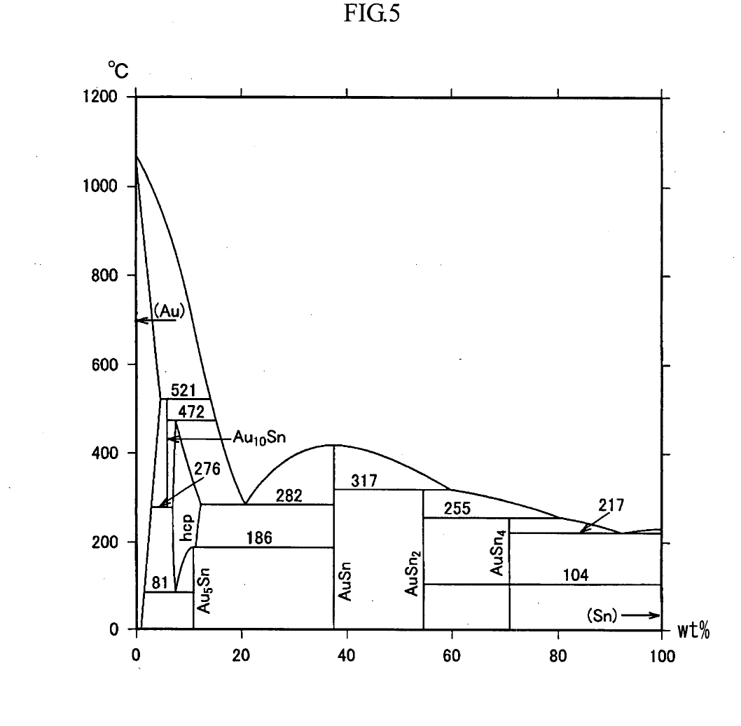

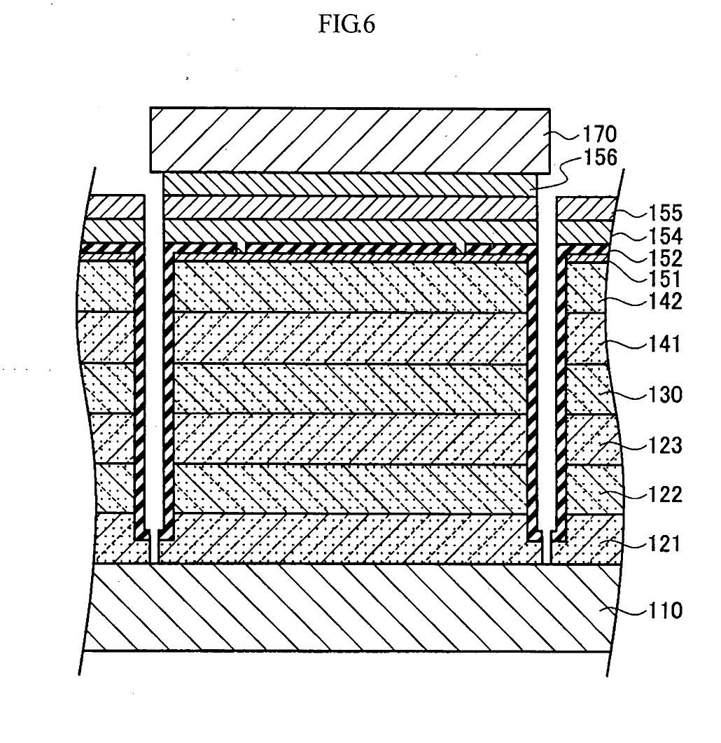

Following the bonding layer forming step, Step S103 in FIG. 2, i.e. a bonding step, is performed. In this step, the first bonding layer 155 is bonded to the second bonding layer 156. FIG. 6 is a sectional view showing a state after the bonding step is performed.

Specifically, first, ICP etching is performed until the growth substrate 110 is exposed in each cut groove. The etching does not etch the nitride semiconductor layer unnecessarily since it is protected by the insulation layer 152. Next, the first bonding layer 155 and the second bonding layer 156 are bonded to each other at a eutectic temperature of the first bonding layer 155 and the second bonding layer 156. The bonding operation is performed under a pressure so that the first bonding layer 155 and the second bonding layer 156 have a total thickness not smaller than 5 μm.

If the first bonding layer 155 and the second bonding layer 156 are made only of Au layers, the temperature for the bonding operation are chosen from a range of 400° C. through 800° C. for example. On the other hand, as shown in a composition chart in FIG. 5, the eutectic temperatures of Au—Sn alloy are 217° C. and 282° C. Thus, if the first bonding layer 155 and the second bonding layer 156 are made of an Au—Sn alloy, the bonding temperature should be within a range of 280° C. through 400° C. for example.

Following the bonding step, Step S104 in FIG. 2, i.e. a removal step is performed. In this step, the growth substrate 110 is removed from the nitride semiconductor layer.

Specifically, first, a KrF laser beam having a wavelength of 248 nm and irradiation energy of 300 through 400 mJ/cm⁻² is applied through the growth substrate 110 to the nitride semiconductor layer. The KrF laser beam transmits the sapphire growth substrate 110 virtually completely, and is absorbed by the n-type buffer layer 121 of GaN virtually completely. Thus, the n-type buffer layer 121 is thermally decomposed, thereby allowing the growth substrate 110 to be removed from the nitride semiconductor layer. As a result of the thermal decomposition N₂ gas occurs, which flows into gaps in the nitride semiconductor layer. Therefore, the N₂ gas does not apply undue pressure onto the nitride semiconductor layer, and there is no risk for the nitride semiconductor layer to be cracked by the gas.

After the thermal decomposition, the n-type buffer layer 121 leaves a residue of Ga under the n-type contact layer 122. The Ga is removed by wet etching with acid, alkali or others. Preferably, the wet etching is followed by dry etching performed to the n-type contact layer 122. The dry etching improves the ohmic contact between the n-type contact layer 122 and the n-electrode 160. The n-electrode 160 is built under the n-type contact layer 122 by forming a Ti layer and an Al layer in this order, or by forming an Al layer alone.

By following the above-described steps, a semiconductor light-emitting element in FIG. 1 is obtained.

Next, description will cover functions of the semiconductor light-emitting element.

The first bonding layer 155, the second bonding layer 156 and the support substrate 170 are built in this order on a main surface of a nitride semiconductor layer. The first bonding layer 155 and the second bonding layer 156 are made of an Au layer or an Au—Sn alloy layer and have a thickness not smaller than 5 μm. Thus, these bonding layers function not only as electric conductors but also as metal layers of a high thermal conductivity capable of conducting heat which is generated by the semiconductor light-emitting element to the support substrate 170. Further, the support substrate 170 has a thermal conductivity not smaller than 100 W/mK. Thus, the support substrate 170 is capable of releasing the heat efficiently from the first bonding layer 155 and the second bonding layer 156. Therefore, even if an increased amount of electric current is applied to the semiconductor light-emitting element in order to increase the output of light, heat generated at the semiconductor light-emitting element is released efficiently from the support substrate 170. Also, it is possible to prevent decrease in the output characteristic of the semiconductor light-emitting element caused by thermal saturation.

Further, according to the manufacturing method described, the first bonding layer 155 and the second bonding layer 156 are bonded to each other at a eutectic temperature and under pressure. Under this operation, the first bonding layer 155 and the second bonding layer 156 become alloyed to provide a strong bond.

According to the manufacturing method described, MOCVD technique is employed to achieve crystalline growth of a nitride semiconductor layers. The present invention is not limited to this; for example, MOCVD technique may be replaced by hydride vapor phase epitaxy (HVPE) or Gas-source MBE technique. Also, crystal structure of the nitride semiconductor layer may be whichever of the wurtzite form and the zinc blende structure. Further, crystal growth plane orientation is not limited to [0001], but may be [11-20] or [1-100].

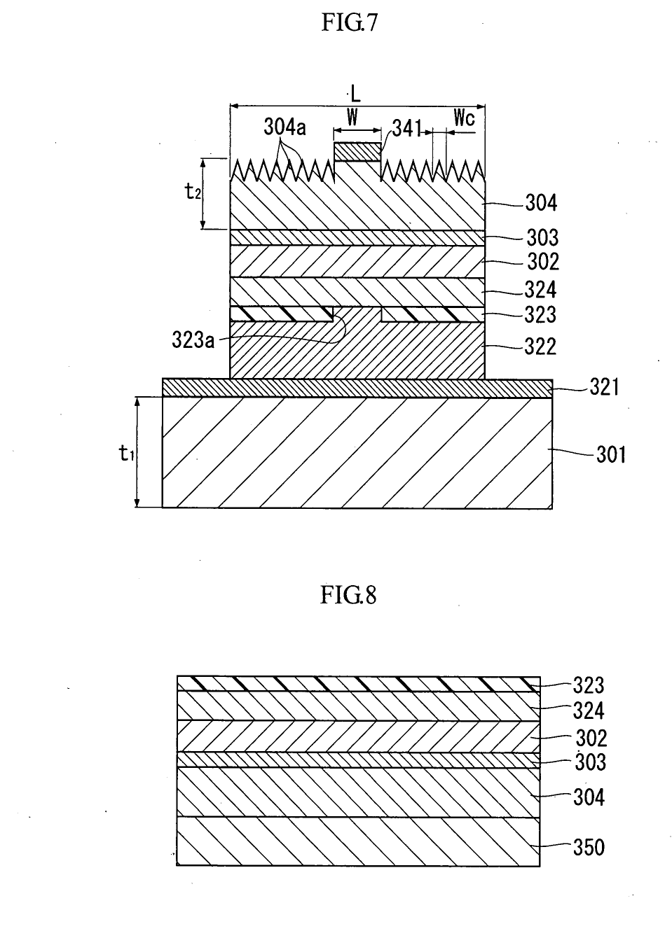

Next, description will cover a semiconductor light-emitting element according to a second embodiment of the present invention, with reference to FIG. 7 through FIG. 12.

As shown in FIG. 7, a semiconductor light-emitting element according to the present embodiment includes a support substrate 301, a p-side electrode 321, a reflection layer 322, a mask layer 323, a ZnO electrode 324, a p—GaN layer 302, an active layer 303, an n—GaN layer 304, and an n-side electrode 341, and is capable of emitting blue light or green light for example.

The support substrate 301 supports the p-side electrode 321, the reflection layer 322, the mask layer 323, the ZnO electrode 324, the p—GaN layer 302, the active layer 303, the n—GaN layer 304 and the n-side electrode 341. The support substrate 301 is formed of e.g. Cu, AlN or other material which has a high thermal conductivity. The support substrate 301 has a thickness t₁ of 200 through 1000 μm.

The p-side electrode 321 is formed to cover the entire upper surface of the support substrate 301. The p-side electrode 321 is made of Au—Sn or Au for example.

The reflection layer 322 is structured by layers of e.g. Al, Ti, Pt and Au, named from the uppermost to the lowermost layer. By including a layer provided by Al which has a relatively high reflection index, the reflection layer 322 is capable of reflecting the light from the active layer 303 in an upper direction. The reflection layer 322 provides electrical connection between the p-side electrode 321 and the ZnO electrode 324. The material Al for the layer may be replaced with Ag.

The mask layer 323 serves as an etching mask in a manufacturing step (to be described later) of the semiconductor light-emitting element, when etching the ZnO electrode 324, the p—GaN layer 302, the active layer 303 and the n—GaN layer 304. The mask layer 323 is made of e.g. a dielectric material such as SiO₂. The mask layer 323 has a through-hole 323a. The through-hole 323a allows contact between the reflection layer 322 and the ZnO electrode 324 thereby establishing electrical connection therebetween.

The ZnO electrode 324, which is made of an electrically conductive transparent oxide ZnO, allows the light from the active layer 303 to pass through while providing electrical connection between the p—GaN layer 302 and the reflection layer 322. The ZnO electrode 324 has an electric resistance of about 2×10⁻⁴ Ωcm and a thickness of 1000 through 20000 Å, for example.

The p—GaN layer 302 is provided by GaN doped with a p-type dopant Mg. An undoped GaN layer (unillustrated) or an In—Ga—N layer (unillustrated) containing about 1% of In is formed between the p—GaN layer 302 and the active layer 303.

The active layer 303 is an MQW layer containing In—Ga—N, serving as an amplification layer of light generated by electron-hole recombination. The active layer 303 is structured by a plurality of In—Ga—N layers. These In—Ga—N layers can be divided into two categories; one having a composition of In_{X}Ga_{1-X}N(0≦x≦0.3) while the other having a composition of In_{Y}Ga_{1-Y}N(0≦Y≦0.1, and Y≦X). The layer provided by In_{X}Ga_{1-X}N is the well layer, while the layer provided by In_{Y}Ga_{1-Y}N is the barrier layer. The well layer and the barrier layer are tiered alternately with each other. A superlattice layer (unillustrated) provided by Si-doped In—Ga—N and GaN is formed between the active layer 303 and the n—GaN layer 304.

The n—GaN layer 304 is provided by GaN doped with an n-type dopant Si. A plurality of projections 304a are formed on an upper surface of the n—GaN layer 304. Each of the projections 304a is conic in shape. In the present embodiment, supposing that the projections 304a have their bottom widths Wc, the average Wc′ of the widths Wc satisfies the relationship Wc′=λ/n, where λ denotes the peak wavelength of the light emitted from the active layer 303, and n denotes the refraction index of the n—GaN layer 304. For instance, when the peak wavelength λ is 460 nm, and the refraction index n of the n—GaN layer 304 is about 2.5, the average width Wc′ is about 184 nm or more. In the present embodiment, the projections 304a have a height of about 2 μm. The n—GaN layer 304 is formed with the n-side electrode 341. The n-side electrode 341 is structured by layers of e.g. Al, Ti, Au or Al, Mo and Au in the order as viewed from the n—GaN layer 304.

In the present embodiment, the n—GaN layer 304 has a thickness t₂ satisfying the following inequality:

$${t}_{2} \geq \frac{ρ {J}_{0} {eW}^{2}}{8 {γκ}_{B} T} log ( \frac{L}{W} ) + x$$

where, x denotes a value not smaller than 0.1 μm and not greater than 3.0 μm, L denotes the representative length of the semiconductor light-emitting element, W denotes the representative length of the n-side electrode 341, T denotes the absolute temperature, J₀ denotes the electric current density at the contact portion between the n-side electrode 341 and the n—GaN layer 304, e denotes the elementary electric charge, y denotes the diode ideality factor, KB denotes the Boltzmann constant, and ρ denotes the specific resistance of the n—GaN layer 304.

The first term in the right-hand side of the inequality determines the thickness t₂ by taking into account the electric current distribution in the n—GaN layer 304. More specifically, the above-mentioned electric current distribution is diffusion of the electric current passing in the n—GaN layer 304, with the n-side electrode 341 viewed at the center. This distribution depends upon the relation between the electric resistance (measured in a cylindrical coordinate system) of the n—GaN layer 304 and the forward-direction current-voltage characteristics of the pn-junction semiconductor. The second term in the right-hand side of the inequality is a term of correction corresponding to the projections 304a.

In the present embodiment, the n-side electrode 341, which is circular, has a diameter W of about 100 μm, and the n—GaN layer 304, which is square, has a side L of about 250 μm. Thus, the thickness t₂ of the n—GaN layer 304 is chosen to be about 1.1 μm. It should be noted here that the representative length of the n-side electrode 341 and that of the semiconductor light-emitting element refer to their diameter if they are circular and to their length of a side if they are square.

Next, a manufacturing method of the semiconductor light-emitting element will be described with reference to FIGS. 8-12.

First, a sapphire substrate 350 is placed in an MOCVD growth chamber. While supplying H₂ gas into the growth chamber, the temperature inside the growth chamber is raised to about 1050° C. to perform the cleaning of the sapphire substrate 350.

Next, as shown in FIG. 8, a GaN buffer layer (unillustrated) is formed on the sapphire substrate 350 by MOCVD with the inner temperature of the growth chamber, or layer formation temperature, kept at about 600° C. Thereafter, the layer formation temperature is raised to about 1000° C. to sequentially form an Si-doped n—GaN layer 304, Si-doped InGaN—GaN superlattice layer (unillustrated), a MQW active layer 303, and an undoped GaN layer or an InGaN layer (unillustrated) containing about 1% of In. Next, an Mg-doped p—GaN layer 302 is formed at a slightly increased layer formation temperature. The p—GaN layer 302 is annealed to activate Mg. Then, a ZnO electrode 324 is formed by molecular beam epitaxy (MBE). Thereafter, a mask layer 323 is formed of SiO₂.

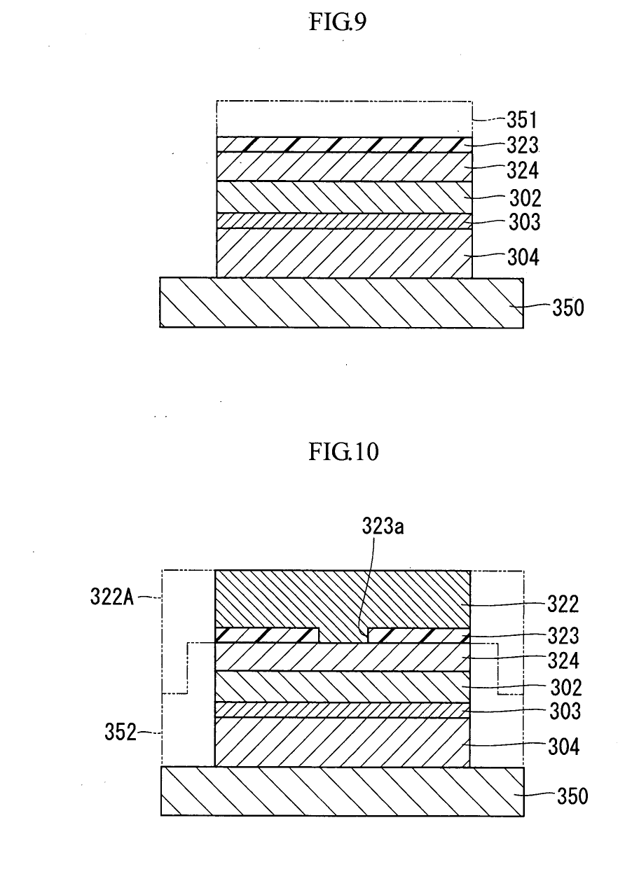

Next, as shown in FIG. 9, a resist film 351 is formed by photolithography. The resist film 351 is used as an etching mask to pattern the mask layer 323, and thereafter the resist film 351 is removed. The mask layer 323 is used in ICP etching, in which the ZnO electrode 324 through the n—GaN layer 304 are subjected to mesa etching.

Next, as shown in FIG. 10, the mask layer 323 is patterned by dry etching with a CF4 gas. Through this process, a through-hole 323a is made in the mask layer 323 in order to establish contact between the reflection layer 322 and the ZnO electrode 324. During this process, the ZnO electrode 324 serves as an etching stopper. After making the through-hole 323a, a resist film 352 is formed. Further, Al or Ag is deposited, and then layers of Ti, Pt and Au are formed sequentially to build a metal layer 322A. Then, by removing the resist film 352 and part of the metal layer 322A, a complete reflection layer 322 is obtained.

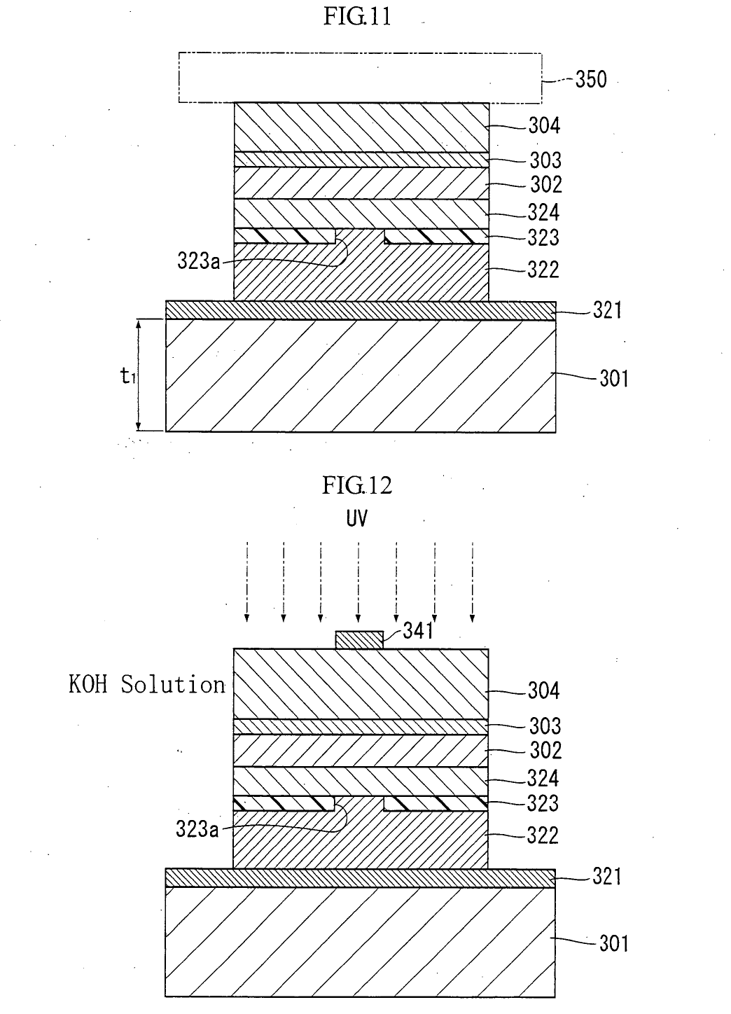

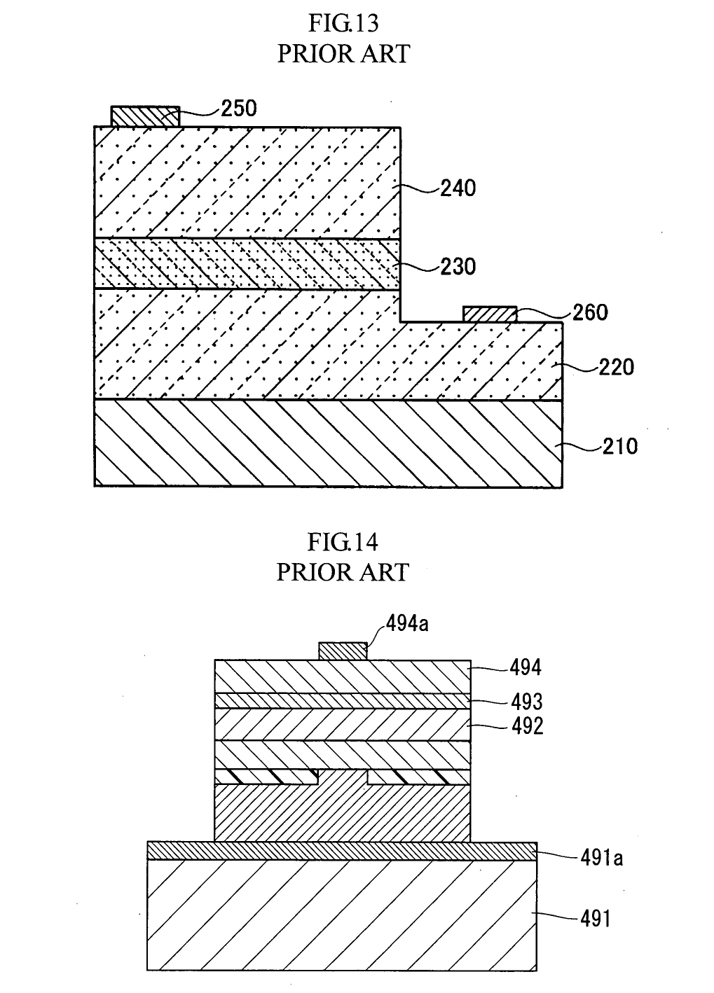

Next, as shown in FIG. 11, a support substrate 301 which has a thickness t₁ of 200 through 1000 μm is prepared, and on this support substrate 301, a p-side electrode 321 of Au—Sn or Au is formed. The p-side electrode 321 and the reflection layer 322 are bonded to each other by thermocompression. Thereafter, the n—GaN layer 304 is irradiated through the sapphire substrate 350 by KrF laser oscillating with a wavelength of 248 nm. The applied laser beam causes the interface between the sapphire substrate 350 and the n—GaN layer 304 (i.e. the above-described GaN buffer layer (unillustrated)) to be heated rapidly. As a result, the n—GaN layer 304 and the GaN buffer layer near the interface melts, thereby enabling the removal of the sapphire substrate 350. Such a technique is called laser lift-off (LLO).

Next, a metal layer (not illustrated) made up of Al, Ti and Au, or a metal layer made up of Al, Mo and Au is formed on the n—GaN layer 304. By patterning this layer, an n-side electrode 341 is formed, as shown in FIG. 12. After the removal of sapphire substrate 350, the surface of n—GaN layer 304 exhibits N polarity, not Ga polarity, in which the surface can easily become anisotropic by etching. The n—GaN layer 4 is irradiated with about 3.5 W/cm² of ultraviolet light for about 10 minutes while being held in a KOH solution of about 4 mol/l at about 62° C. As a result, a plurality of projections 304a, having bottom widths Wc and their average Wc′ satisfying the above-described relationship, are formed on the surface of n—GaN layer 304. Further, the thickness t₂ of the n—GaN layer 4 is made to satisfy the above inequality.

Next, the functions of the semiconductor light-emitting element according to the present embodiment will be described.

The thickness t₁ of the support substrate 301 is not smaller than 200 μm, which prevents the support substrate 301 from breaking unexpectedly during the manufacturing process of the semiconductor light-emitting element. This increases the yield rate of the semiconductor light-emitting elements. Further, in the manufacture of semiconductor light-emitting elements, a plurality of the elements are produced by dicing a large support substrate 301, with a dicing tape attached to the lower surface of the support substrate 301. By making the thickness t₁ of the support substrate 301 not greater than 1000 μm, it is possible to allow the support substrate 301 to flex appropriately upon dicing. This prevents the support substrate 301 from coming off the dicing tape, thereby improving the yield rate in the manufacturing process.

Further, the support substrate 301 has a relatively high thermal conductivity since it is formed of Cu or AlN. Thus, the support substrate 301 can function as a good dissipater of heat generated by the semiconductor light-emitting element in operation.

Since the n—GaN layer 304 has the thickness t₂ which satisfies the inequality described above, it is possible to allow the electric current from the n-side electrode 341 to spread sufficiently in in-plane or longitudinal directions of the n—GaN layer 304 before the current has passed through in the thickness direction of the layer 304. Thus, the current can flow the entire regions of the n—GaN layer 304, the active layer 303 and the p—GaN layer 302. Accordingly, it is possible to generate light by using the entire active layer 303, and hence to increase the amount of light generated by the semiconductor light-emitting element.

Further, due to the projections 304a formed on the n—GaN layer 304, it is possible to prevent the surface of the n—GaN layer 304 from causing the total internal reflection of light coming from the active layer 303. This serves to increase the amount of light emission from the n—GaN layer 304, and thereby providing a brighter semiconductor light-emitting element.

1. A semiconductor light-emitting element comprising:
a nitride semiconductor layer including an active layer;
a first bonding layer provided on a main surface of the nitride semiconductor layer and made of gold or an alloy of gold and tin;
a second bonding layer bonded to the first bonding layer and made of gold or an alloy of gold and tin; and
a support substrate bonded to the second bonding layer and having a thermal conductivity not smaller than 100 W/mK;
wherein the first bonding layer and the second bonding layer have a total thickness not smaller than 5 μm.

2. A method of manufacturing a semiconductor light-emitting element, the method comprising:
a step of forming a nitride semiconductor layer on a growth substrate, the nitride semiconductor layer including an active layer;
a layering step of forming a first bonding layer on a main surface of the nitride semiconductor layer, the first bonding layer being made of gold or an alloy of gold and tin;
a bonding layer forming step of forming a second bonding layer on a main surface of a support substrate, the second bonding layer being made of gold or an alloy of gold and tin, the support substrate having a thermal conductivity not smaller than 100 W/mK;
a bonding step of bonding the first and the second bonding layers to each other under a pressure at a eutectic temperature of the first bonding layer and the second bonding layer; and
a removal step of removing the growth substrate from the nitride semiconductor layer;
wherein the first bonding layer and the second bonding layer after bonded to each other have a total thickness not smaller than 5 μm.

3. A semiconductor light-emitting element comprising:
a substrate;
a p-type semiconductor layer supported by the substrate;
an n-type semiconductor layer disposed farther away from the substrate than the p-type semiconductor layer; and
an active layer disposed between the p-type semiconductor layer and the n-type semiconductor layer;
wherein the substrate has a thickness not smaller than 200 μm and not greater than 1000 μm.

4. The semiconductor light-emitting element according to claim 3, wherein the substrate is made of Cu or AlN.
